(19) United States
(12) Patent Application Publication
(10) Pub. No.: US 2011/0304810 A1
(43) Pub. Date: Dec. 15, 2011

(54) TOUCH PANEL, DISPLAY APPARATUS INCLUDING THE SAME, AND METHOD FOR MANUFACTURING THE SAME

(76) Inventors: Seung-Jin KIM, Asan-si (KR); Sung-Hwan Bae, Cheonan-si (KR)

(21) Appl. No.: 13/160,429

(22) Filed: Jun. 14, 2011

(30) Foreign Application Priority Data
Jun. 14, 2010 (KR) 10-2010-0056022

(51) Int. Cl. G02F 1/1339; H05K 3/00; B32B 37/12; B32B 7/02; B32B 37/02

(52) U.S. Cl. 349/153; 428/212; 156/292

(57) ABSTRACT

A touch panel and a display apparatus including the same, and a method for manufacturing the same. The touch panel includes a first substrate having a first surface and a transparent electrode formed on the first surface, a second substrate spaced a predetermined distance apart from the first substrate and having a second transparent electrode formed on a surface facing the first surface of the first substrate, a plurality of dot spacers formed on the first transparent electrode and made of a first elastomeric material, and an adhesion member interposed between the first substrate and the second substrate, adhering the first substrate to the second substrate, and comprising a second elastomeric material having substantially the same thermal expansion coefficient as that of the first elastomeric material.

### CROSS-REFERENCE TO RELATED APPLICATION

This application claims priority from Korean Patent Application No. 10-2010-0056022 filed on Jun. 14, 2010 in the Korean Intellectual Property Office, the disclosure of which is incorporated herein by reference in its entirety.

### BACKGROUND OF THE INVENTION

1. Field of the Invention

The present invention relates generally to flat panel displays. More specifically, the present invention relates to touch panels and their manufacture.

2. Description of the Related Art

Generally, a touch panel is a device that can detect the position of a touch within its display area, eliminating the need for a keyboard. The touch panel senses positional coordinates of a finger or other object pointing to a particular portion of the panel (typically pointing at a letter or an image displayed) without using a keyboard or other input device, and performs some subsequent desired process in response.

There are various types of touch panels such as, for example, a capacitive-type, a resistive-type, or an infrared sensing type touch panel. In particular, resistive type touch panels are widely used because they are relatively thin and light. The resistive-type touch panel is typically used with a liquid crystal display, which is also often lightweight, small and thin.

FIG. 1 is a cross-sectional view of a conventional resistive-type touch panel.

Referring to FIG. 1, a touch panel 100 includes a first substrate 110, a second substrate 120 spaced a predetermined distance apart from the first substrate 110, and first and second transparent electrodes 130 and 140 formed on inner surfaces of the first and second substrates 110 and 120, respectively, so as to face each other.

Here, a plurality of dot spacers 150 are formed on the first transparent electrode 130. The dot spacers 150 maintain a gap between the first and second transparent electrodes 130 and 140. A height of each of the dot spacers 150 is smaller than the distance between the first and second transparent electrodes 130 and 140.

In addition, an adhesion member 160 for adhering the first substrate 110 and the second substrate 120 to each other is interposed between the surfaces facing the first and second substrates 110 and 120.

Operation of the resistive-type touch panel will now be described briefly. That is to say, during a state in which a voltage is applied to the first and second transparent electrodes 130 and 140 by allowing current flow through the first and second transparent electrodes 130 and 140, a specific area of the second substrate 120 is pressed by a finger or a pen. This deforms the second substrate 120, so that the first and second transparent electrodes 130 and 140 come into contact with each other at the pressed position. A change in the resistance occurs at the contact point of the first and second transparent electrodes 130 and 140, and voltage values may change according to this change in the resistance. The change in the voltage value is read, thereby detecting the contact position.

In the conventional touch panel, a double sided tape is used as the adhesion member 160 and the dot spacers 150 are made of an insulating material, such as epoxy or silicon.

This configuration has its drawbacks, however. As one example, repeated pressing on the second substrate 120 deforms both substrate 120 and transparent electrode 140, resulting eventually in wear and deterioration of the transparent electrode 140.

In addition, a distribution of the contact sensitivity levels and the center value thereof may change depending on various factors, including stress applied in the course of attaching the double-sided tape as the adhesion member 160, a distribution of the dot spacers 150, a thickness of the double-sided tape, mechanical strengths of the substrates 110 and 120, and so on. As a result, contact sensitivity may vary with time.

Further, when reliability tests are conducted on the conventional touch panel, moisture may infiltrate into a space between the first and second transparent electrodes 130 and 140, resulting in migration between the first and second transparent electrodes 130 and 140.

### SUMMARY OF THE INVENTION

The present invention provides a touch panel which better prevents a transparent electrode from deteriorating, and which has improved touch sensitivity.

The present invention also provides a method for manufacturing a touch panel, which can simplify its manufacturing process while better preventing the transparent electrode from deteriorating and exhibiting improved contact sensitivity.

The present invention also provides a display apparatus including the touch panel.

The present invention also provides a method for manufacturing a display apparatus including the touch panel.

The above and other objects of the present invention will be described in or be apparent from the following description of the preferred embodiments.

According to an aspect of the present invention, there is provided a touch panel including a first substrate having a first surface and a transparent electrode formed on the first surface, and a second substrate spaced a predetermined distance apart from the first substrate and having a second transparent electrode formed on a surface facing the first surface of the first substrate. A plurality of dot spacers is formed on the first transparent electrode and made of a first elastomeric material, and an adhesion member is interposed between the first substrate and the second substrate, adhering the first substrate to the second substrate, and comprising a second elastomeric material having substantially the same thermal expansion coefficient as that of the first elastomeric material.

According to another aspect of the present invention, there is provided a liquid crystal display integrated with a touch panel. The liquid crystal display includes a display panel including a first substrate having a first surface, a thin film transistor and a pixel electrode formed on the first surface, a second substrate generally spaced a predetermined distance apart from the first substrate and having color filters and a common electrode formed on a surface of the second substrate facing the first surface of the first substrate, and a liquid crystal layer interposed between the first substrate and the second substrate. The display panel is also adapted to display an image. The liquid crystal display also includes a first transparent electrode formed on a surface of the second substrate that is opposite to the surface of the second substrate facing the first surface of the first substrate, as well as a third substrate having a second transparent electrode formed on a surface of the third substrate facing the first transparent electrode. The liquid crystal display further includes a plurality of dot spacers formed on the first transparent electrode and comprising a first elastomeric material, and an adhesion member interposed between the second substrate and the third substrate. The adhesion member adheres the second substrate and the third substrate to each other and comprises a second elastomeric material having substantially the same thermal expansion coefficient as that of the first elastomeric material.

According to still another aspect of the present invention, there is provided a method for manufacturing a touch panel including forming a first transparent electrode on a first substrate, forming a plurality of dot spacers on the first transparent electrode, the plurality of dot spacers comprising a first elastomeric material, and forming a second transparent electrode on a second substrate. The method also includes forming an adhesion member on one of the first transparent electrode and the second transparent electrode, the adhesion member comprising a second elastomeric material having substantially the same thermal expansion coefficient as that of the first elastomeric material. After the forming a plurality of dot spacers and the forming an adhesion member, the method includes attaching the first substrate and the second substrate to each other such that the adhesion member couples the first substrate to the second substrate, and the first transparent electrode and the second transparent electrode face each other.

According to still another aspect of the present invention, there is provided a method for manufacturing a liquid crystal display integrated with a touch panel, the method including preparing a display panel that comprises a first substrate having a first surface, a thin film transistor and a pixel electrode on the first surface, a second substrate generally spaced a predetermined distance apart from the first substrate and having color filters and a common electrode formed on a surface of the second substrate facing the first surface of the first substrate, and a liquid crystal layer interposed between the first substrate and the second substrate. The display panel is adapted to display an image. The method further includes forming a first transparent electrode on a surface of the second substrate that is opposite to the surface of the second substrate facing the first surface of the first substrate, and forming a plurality of dot spacers on the first transparent electrode, the dot spacers comprising a first elastomeric material. The method also includes forming a second transparent electrode on a third substrate, and forming an adhesion member on one of the first transparent electrode and the second transparent electrode, the adhesion member comprising a second elastomeric material having substantially the same thermal expansion coefficient as that of the first elastomeric material. After the forming a plurality of dot spacers and the forming an adhesion member, the method includes attaching the second substrate and the third substrate to each other such that the adhesion member couples the second substrate to the third substrate, and the first transparent electrode and the second transparent electrode face each other.

### BRIEF DESCRIPTION OF THE DRAWINGS

The above and other features and advantages of the present invention will become more apparent by describing in detail preferred embodiments thereof with reference to the attached drawings in which:

FIG. 1 is a cross-sectional view of a conventional resistive-type touch panel;

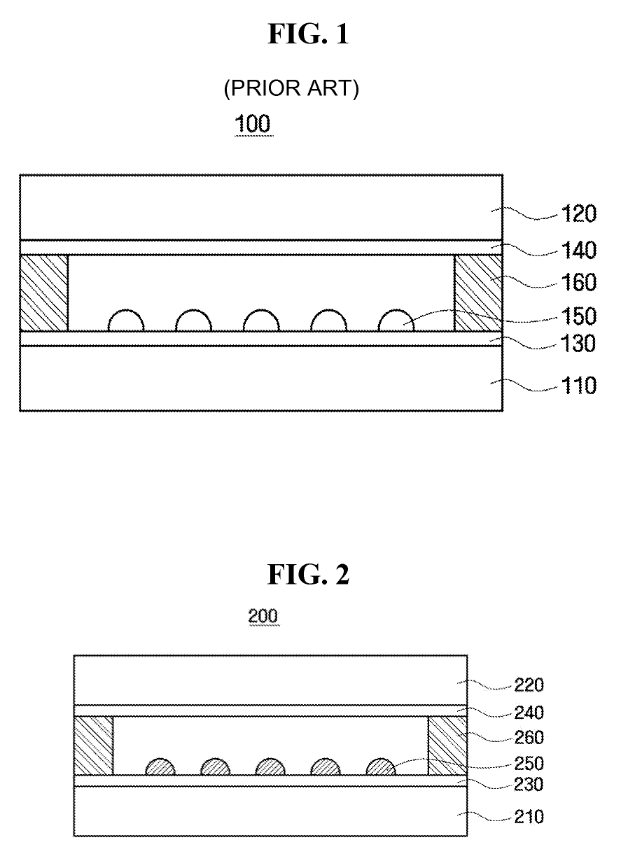

FIG. 2 is a cross-sectional view of a resistive-type touch panel according to an embodiment of the present invention;

FIG. 3 is a cross-sectional view of a liquid crystal display (LCD) according to an embodiment of the present invention;

FIGS. 4A through 4C are cross-sectional views illustrating a method for manufacturing a touch panel according to a first embodiment of the present invention;

FIGS. 5A through 5C are cross-sectional views illustrating a method for manufacturing a touch panel according to a second embodiment of the present invention; and

FIGS. 6A through 6D are cross-sectional views illustrating a method for manufacturing of a liquid crystal display (LCD) according to an embodiment of the present invention.

Like reference numerals refer to corresponding parts throughout the drawings.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the thicknesses of layers and regions are exaggerated for clarity, and are not necessarily to scale.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Hereinafter, exemplary embodiments of the present invention will be described in detail with reference to the accompanying drawings.

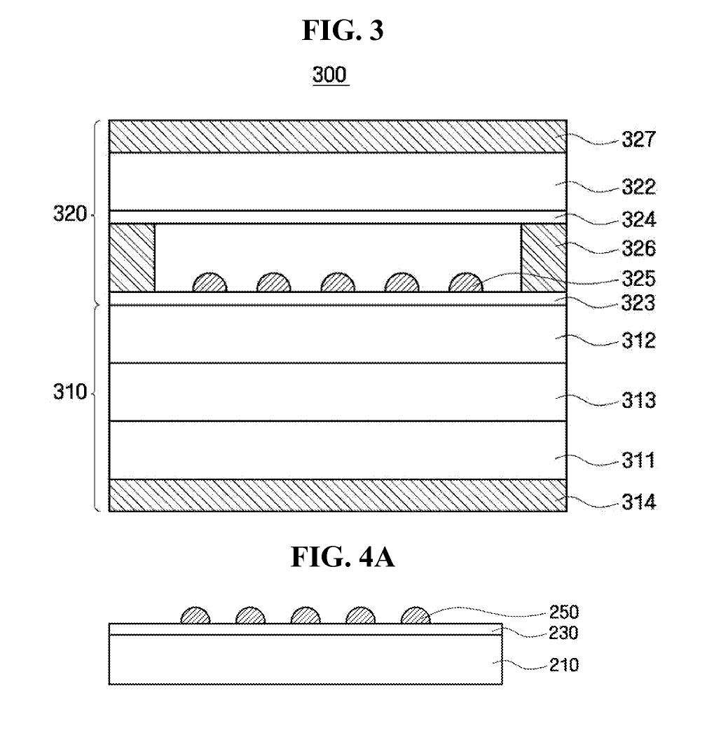

FIG. 2 is a cross-sectional view of a resistive-type touch panel according to an embodiment of the present invention.

Referring to FIG. 2, the touch panel 200 includes a first substrate 210 having a first transparent electrode 230 formed on its inner surface (i.e. the surface facing the substrate 220), a second substrate 220 spaced a predetermined distance apart from the first substrate 210 and having a second transparent electrode 240 formed on an inner surface facing the inner surface of the first substrate 210, a plurality of dot spacers 250 formed on the first transparent electrode 230, and an adhesion member 260 interposed between the first substrate 210 and the second substrate 220 and adhering the first substrate 210 and the second substrate 220 to each other.

Here, each of the first substrate 210 and the second substrate 220 includes an active area within which a pressing operation can be detected, and an inactive area disposed outside, and at the periphery of, the active area. In addition, the first substrate 210 and/or the second substrate 220 may be a glass substrate or an optical film made of a material such as polyethylene terephthalate (PET), or polycarbonate.

The first transparent electrode 230 and/or the second transparent electrode 240 may be made of a transparent conductive material such as indium tin oxide (ITO) or indium zinc oxide (IZO). Although not shown, a pair of electrode bars may be disposed at both sides of the first transparent electrode 230 to apply a voltage to the first transparent electrode 230 generally in one direction, for example, in the X-axis direction. Another pair of electrode bars may be disposed at both sides of the second transparent electrode 240 to apply a voltage to the second transparent electrode 240 in a direction generally crossing the one direction, for example, in the Y-axis direction.

The dot spacers 250 include a plurality of dot spacers formed on the first transparent electrode 230 and in the active area. The dot spacers 250 are formed for the purpose of maintaining a gap between the first transparent electrode 230 and the second transparent electrode 240, and a height of each of the spacers 250 is smaller than the gap between the first transparent electrode 230 and the second transparent electrode 240. Although the dot spacers 250 are shown as having a generally hemispherical shape, aspects of the present invention are not limited thereto. That is to say, the dot spacers 250 may have any suitable shape, for example a generally cylindrical shape or some other shape.

The adhesion member 260 is interposed between the inner surface of the first substrate 210 and the inner surface of the second substrate 220 in the inactive area. As described above, the inactive area is disposed at the periphery of the active area. Therefore, if the first substrate 210 and the second substrate 220 have the same shape, for example, a generally rectangular plate shape, the adhesion member 260 can be formed along the periphery of the rectangular plate. Therefore the adhesion member 260 may be shaped generally as a frame, surrounding the active area.

In the illustrated embodiment, the dot spacers 250 and the adhesion member 260 are formed using a first elastomeric material and a second elastomeric material, respectively. Specifically, the dot spacers 250 and the adhesion member 260 are formed using one or more elastomeric materials having approximately the same thermal expansion coefficient. The term “elastomeric material,” as used herein, means a polymeric compound capable of largely returning to its original dimensions after it is deformed due to an external force. To impart the same thermal expansion coefficient to the first elastomeric material and the second elastomeric material, the first elastomeric material and the second elastomeric material may be the same material. In this case, there are the following benefits and advantages.

First, since an elastomeric material has elasticity, adhesion members 260 formed using the first elastomeric material compress when the second substrate 220 is pressed, reducing the amount of deformation that the second transparent electrode 240 undergoes. That is, the compliance of the adhesion members 260 reduces the deformation of, and therefore the stress on, the second transparent electrode 240. This in turn helps prevent deterioration of the second transparent electrode 240, improving its reliability and lifespan.

In addition, since the dot spacers 250 and the adhesion member 260 have elasticity and the same thermal expansion coefficient, the stress applied to the periphery is lessened, as compared to the conventional process in which a double-sided tape is attached to the periphery of the active area. Further, according to the current embodiment, the operation ranges of the second substrate 200 are substantially the same with each other in the active area and the inactive area, thereby improving the contact sensitivity.

Further, as described above, when the first elastomeric material and the second elastomeric material are the same material, that is to say, when the dot spacers 250 and the adhesion member 260 are made of the same elastomeric material, not only do the above-described benefits and advantages accrue, but also the manufacture of the touch panel is simplified. This is further explained below.

Each of the first elastomeric material and the second elastomeric material includes a material having an elastic coefficient in a range of approximately 5-15 gf/μm. When the elastic coefficient is less than about 5 gf/μm, the dot spacers 250 and the adhesion member 260 are too soft to return to their original dimensions after the second substrate 240 is pressed. When the elastic coefficient is greater than about 15 gf/μm, the adhesion member 260 is too hard, leading to some of the same problems generated in conventional touch panels.

Each of the first elastomeric material and/or the second elastomeric material may include a rubber-resin composition. The rubber-resin composition in turn may include at least one of polyurethane, polyester or nitrile butadiene rubber.

Here, when the rubber-resin composition for forming the second elastomeric material includes an anti-hygroscopic resin such as polyester, the following benefits and advantages in addition to the above-described benefits and advantages are demonstrated.

That is to say, even under high-temperature and high-humidity conditions, it is quite difficult for moisture to pass through the adhesion member 260 to then infiltrate into the touch panel 200, thereby preventing defects due to moisture penetration, such as inter-electrode migration.

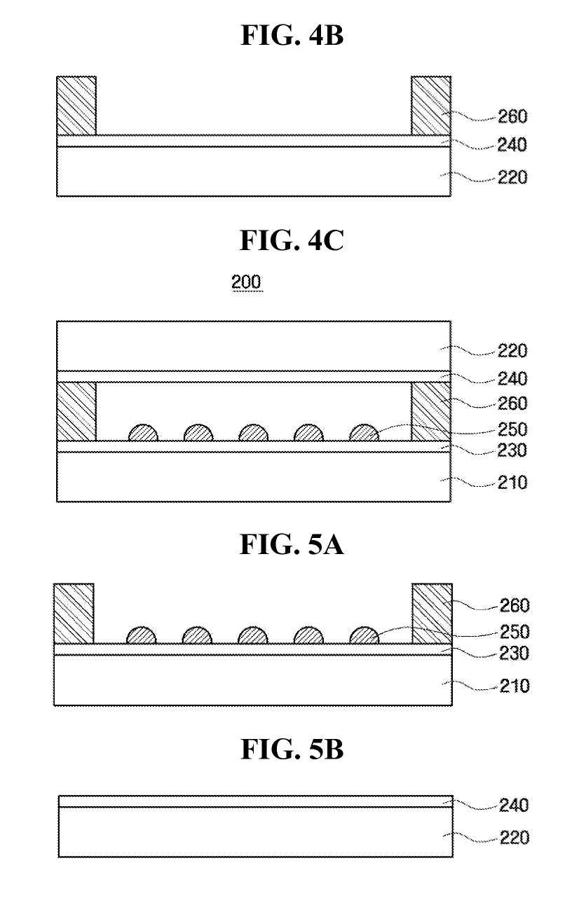

FIG. 3 is a cross-sectional view of a liquid crystal display (LCD) according to an embodiment of the present invention. Here, the LCD of the current embodiment includes a touch panel having substantially the same configuration as that shown in FIG. 2.

Referring to FIG. 3, the LCD 300 includes a display panel 310 that displays a predetermined image, a backlight assembly (not shown) disposed under the display panel 310 and supplying the display panel 310 with light, and a touch panel 320 that is both disposed on a top surface of the display panel 310 and integrated with the display panel 310.

More specifically, the display panel 310 includes a lower substrate 311 having thin film transistors (not shown) formed on its inner surface, an upper substrate 312 spaced a predetermined distance apart from the lower substrate 311, a plurality of color filters (not shown) formed on a surface facing the lower substrate 311, liquid crystals 313 injected into a space between the lower substrate 311 and the upper substrate 312, and a first polarizer plate 314 disposed on a bottom surface of the lower substrate 311.

Pixel electrodes (not shown) are formed over and connected to the thin film transistors, and drive the liquid crystals 313 according to the voltage applied thereto via the thin film transistors. A common electrode (not shown) that drives the liquid crystals 313 is formed on the color filters formed on the upper substrate 312, the common electrode corresponding in position to the pixel electrodes. The pixel electrode and the common electrode may be formed using a transparent conductive material such as indium tin oxide (ITO) or indium zinc oxide (IZO).

The first polarizer plate 314 changes the light incident from the backlight assembly (disposed under the display panel 310) into linear polarized light.

The touch panel 320 includes a first transparent electrode 323 formed on a top surface of the upper substrate 312 of the display panel 310, an upper substrate 322 spaced a predetermined distance apart from the upper substrate 312 and having a second transparent electrode 324 formed on a surface facing the top surface of the upper substrate 312 of the display panel 310, a plurality of dot spacers 325 formed on the first transparent electrode 323, an adhesion member 326 interposed between the upper substrate 312 and the upper substrate 322 and adhering the upper substrate 312 and the upper substrate 322 to each other, and a second polarizer plate 327 disposed on the top surface of the upper substrate 322.

The touch panel 320 according to the illustrated embodiment has substantially the same configuration as the touch panel 200 shown in FIG. 2, except that the first substrate 210 of the touch panel 200 shown in FIG. 2 is replaced by the upper substrate 312 included in the display panel 310, and a second polarizer plate 327 is further provided on the top surface of the upper substrate 322. That is to say, the second substrate 220, the first transparent electrode 230, the second transparent electrode 240, the dot spacers 250, and the adhesion member 260 of FIG. 2 are the same as and correspond to the upper substrate 322, the first transparent electrode 323, the second transparent electrode 324, the dot spacers 325, and the adhesion member 326, respectively.

Therefore, the dot spacers 325 and the adhesion member 326 are formed using elastomeric materials having substantially the same thermal expansion coefficient, as described above with reference to FIG. 2. Accordingly, a detailed description thereof will be omitted.

In the LCD 300 of the illustrated embodiment, since the upper substrate 312 included in the display panel 310 serves as a lower substrate of the touch panel 320 as well, a separate lower substrate need not necessarily be provided in the touch panel 320. Accordingly, a thickness of the LCD 300 may be reduced.

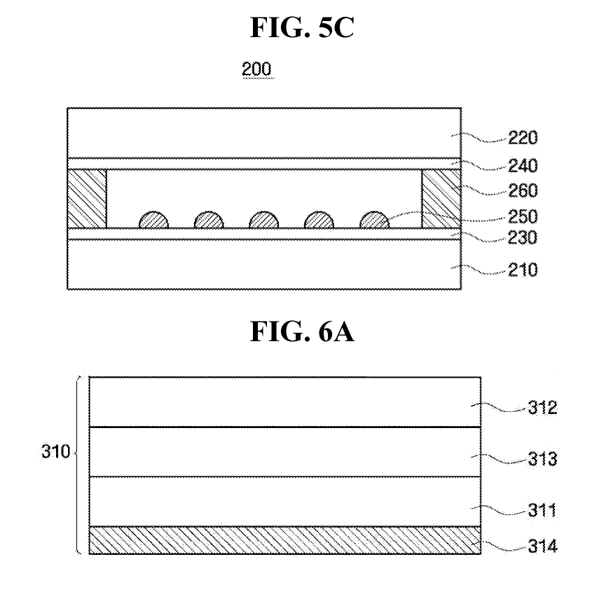

FIGS. 4A through 4C are cross-sectional views illustrating a method for manufacturing a touch panel according to a first embodiment of the present invention.

First, referring to FIG. 4A, a first transparent electrode 230 is formed on the first substrate 210. The first transparent electrode 230 may be formed by sputtering ITO or IZO on the first substrate 210, for example.

Next, a plurality of dot spacers 250 made of a first elastomeric material are formed on the first transparent electrode 230. Here, the plurality of dot spacers 250 are formed in the aforementioned active area and may be formed in any arrangement, such as randomly on the first transparent electrode 230. The dot spacers 250 may be formed by coating or printing the first elastomeric material on the area of the first transparent electrode 230 upon which dot spacers are to be formed, and performing a thermal curing process. Here, a profile of the dot spacers 250 can be adjusted by appropriately adjusting a heating temperature and a heating time during the thermal curing process, as is known.

Referring to FIG. 4B, a second transparent electrode 240 is formed on the second substrate 220. The second transparent electrode 240 may be formed by sputtering ITO or IZO on the second substrate 220, for example.

Next, an adhesion member 260, made of a second elastomeric material having the same thermal expansion coefficient with the first elastomeric material (i.e., the first and second elastomeric materials may be the same material, or may be different materials having substantially the same thermal expansion coefficient), is formed on the second transparent electrode 240. Here, the adhesion member 260 is formed in the aforementioned inactive area, that is, along the edge of the second transparent electrode 240. The adhesion member 260 may be formed by coating or printing the second elastomeric material on a periphery of the second transparent electrode 240 and performing a thermal curing process.

Referring to FIG. 4C, the resultant product of the manufacturing process shown in FIG. 4A, which is the first substrate 210 having the first transparent electrode 230 and the dot spacers 250 formed thereon, and the resultant product of the manufacturing process shown in FIG. 4B, which is the second substrate 220 having the second transparent electrode 240 and the adhesion member 260 formed thereon, are adhered to each other. The adhesion member 260 formed on the second transparent electrode 240 adheres the first transparent electrode 230 and the second transparent electrode 240 to each other, and maintains a distance between the first transparent electrode 230 and the second transparent electrode 240.

The above-described embodiment illustrates that the adhesion member 260 is formed on the second transparent electrode 240, but aspects of the present invention are not limited thereto. That is, the adhesion member 260 may also be formed on the first transparent electrode 230.

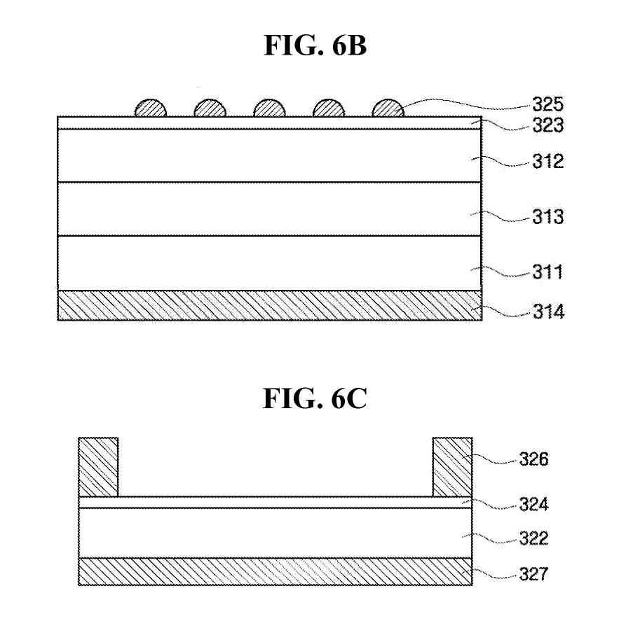

Further, when the first elastomeric material for forming the dot spacers 250 and the second elastomeric material for forming the adhesion member 260 are the same material, the dot spacers 250 and the adhesion member 260 may be formed on the first transparent electrode 230 at the same time, which will be described below in more detail with reference to FIGS. 5A through 5C.

FIGS. 5A through 5C are cross-sectional views illustrating a method for manufacturing a touch panel according to a second embodiment of the present invention.

Referring first FIG. 5A, a first transparent electrode 230 is formed on the first substrate 210. The first transparent electrode 230 may be formed by sputtering ITO or IZO on the first substrate 210, for example.

Next, the plurality of dot spacers 250 and the adhesion member 260, both made of the same elastomeric material, are formed on the first transparent electrode 230. In more detail, the elastomeric material is coated or printed on an area on the first transparent electrode 230 where dot spacers are to be formed, to a first thickness, and the elastomeric material is coated or printed on the periphery of the first transparent electrode 230 to a second thickness greater than the first thickness. This is followed by performing a thermal curing process, thereby forming the dot spacers 250 and the adhesion member 260. In this manner, the dot spacers 250 and adhesion member 260 are formed substantially simultaneously, meaning that the dot spacers 250 and member 260 are both formed during the same coating/printing operation, or both are formed in subsequent coating/printing steps that take place after the forming of transparent electrode 230.

Referring to FIG. 5B, a second transparent electrode 240 is formed on the second substrate 220. The second transparent electrode 240 may be formed by sputtering ITO or IZO on the second substrate 220, for example.

Next, referring to FIG. 5C, the resultant product formed by the manufacturing process of FIG. 5A, which is the first substrate 210 having the first transparent electrode 230, the dot spacers 250 and the adhesion member 260 formed thereon, and the resultant product of the manufacturing process shown in FIG. 5B, which is the second substrate 220 having the second transparent electrode 240 formed thereon, are adhered to each other.

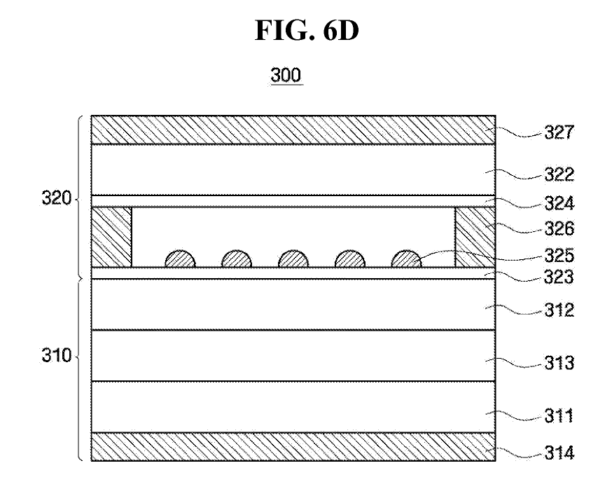

FIGS. 6A through 6D are cross-sectional views illustrating a method for manufacturing of a liquid crystal display (LCD) according to an embodiment of the present invention.

First, referring to FIG. 6A, a display panel 310 that displays an image is formed.

Specifically, a lower substrate 311 is provided, and thin film transistors (not shown) and pixel electrodes (not shown) are then formed on one surface of the lower substrate 311.

Subsequently, a first polarizer plate 314 that changes incident light into linear polarized light is formed on the bottom surface of the lower substrate 311, opposite to the thin film transistors and pixel electrodes. In the illustrated embodiment, the thin film transistors and pixel electrodes are formed on one surface of the lower substrate 311 and the first polarizer plate 314 is then formed on the opposite surface, but the formation sequence may be reversed.

Next, an upper substrate 312 is provided, and a plurality of color filters (not shown) and a common electrode (not shown) are then formed on one surface of the upper substrate 312.

Then, the lower substrate 311 and the upper substrate 312 are adhered to each other such that the upper surface of the lower substrate 311 faces the lower surface of the upper substrate 312, and liquid crystals 313 are injected into a space therebetween, thereby completing the display panel 310.

Referring to FIG. 6B, a first transparent electrode 323 is formed on the top surface of the upper substrate 312, opposite to the color filters and common electrode.

Next, a plurality of dot spacers 325 made of a first elastomeric material are formed on the first transparent electrode 323. The method of forming the dot spacers 325 can be the same as that shown in FIG. 4A.

Referring to FIG. 6C, a second polarizer plate 327 is attached to one surface of an upper substrate 322, and a second transparent electrode 324 is formed on the opposite surface.

Subsequently, an adhesion member 326, made of a second elastomeric material having the same thermal expansion coefficient as the first elastomeric material, is formed on the periphery of the second transparent electrode 324. The method of forming the adhesion member 326 may be the same as that shown in FIG. 4B. As previously stated, the first and second elastomeric materials may be substantially the same material, or different materials having substantially the same (or at least sufficiently similar) thermal expansion properties.

Referring to FIG. 6D, the resultant product of the manufacturing process shown in FIG. 6B and the resultant product of the manufacturing process shown in FIG. 6C are adhered to each other.

The above-described embodiment illustrates that the adhesion member 325 is formed on the second transparent electrode 324, but aspects of the present invention are not limited thereto. That is, the adhesion member 325 may also be formed on the first transparent electrode 323.

Further, when the first elastomeric material for forming the dot spacers 325 and the second elastomeric material for forming the adhesion member 326 are the same material, the dot spacers 325 and the adhesion member 326 may be formed on the first transparent electrode 323 at the same time, as described above with reference to FIGS. 5A through 5C. Accordingly, a detailed description thereof will be omitted.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A touch panel comprising:
a first substrate having a first surface and a transparent electrode formed on the first surface;
a second substrate spaced a predetermined distance apart from the first substrate and having a second transparent electrode formed on a surface facing the first surface of the first substrate;
a plurality of dot spacers formed on the first transparent electrode and made of a first elastomeric material; and
an adhesion member interposed between the first substrate and the second substrate, adhering the first substrate to the second substrate, and comprising a second elastomeric material having substantially the same thermal expansion coefficient as that of the first elastomeric material.

2. The touch panel of claim 1, wherein the first elastomeric material comprises the same material as the second elastomeric material.

3. The touch panel of claim 1, wherein at least one of the first elastomeric material and the second elastomeric material comprises a rubber-resin composition.

4. The touch panel of claim 3, wherein the rubber-resin composition comprises at least one of polyurethane, polyester and nitrile butadiene rubber.

5. The touch panel of claim 1, wherein the second elastomeric material comprises a rubber-resin composition including an anti-hygroscopic resin.

6. The touch panel of claim 1, wherein each of the first elastomeric material and the second elastomeric material has an elastic coefficient in a range of about 5 to 15 gf/μm.

7. A liquid crystal display integrated with a touch panel, the liquid crystal display comprising:
a display panel including:
a first substrate having a first surface, a thin film transistor and a pixel electrode formed on the first surface,
a second substrate generally spaced a predetermined distance apart from the first substrate and having color filters and a common electrode formed on a surface of the second substrate facing the first surface of the first substrate, and
a liquid crystal layer interposed between the first substrate and the second substrate,
the display panel adapted to display an image;
a first transparent electrode formed on a surface of the second substrate that is opposite to the surface of the second substrate facing the first surface of the first substrate;
a third substrate having a second transparent electrode formed on a surface of the third substrate facing the first transparent electrode;
a plurality of dot spacers formed on the first transparent electrode and comprising a first elastomeric material; and
an adhesion member interposed between the second substrate and the third substrate, adhering the second substrate and the third substrate to each other and comprising a second elastomeric material having substantially the same thermal expansion coefficient as that of the first elastomeric material.

8. A method for manufacturing a touch panel comprising:
forming a first transparent electrode on a first substrate;
forming a plurality of dot spacers on the first transparent electrode, the plurality of dot spacers comprising a first elastomeric material;
forming a second transparent electrode on a second substrate;
forming an adhesion member on one of the first transparent electrode and the second transparent electrode, the adhesion member comprising a second elastomeric material having substantially the same thermal expansion coefficient as that of the first elastomeric material; and
after the forming a plurality of dot spacers and the forming an adhesion member, attaching the first substrate and the second substrate to each other such that the adhesion member couples the first substrate to the second substrate, and the first transparent electrode and the second transparent electrode face each other.

9. The method of claim 8, wherein the first elastomeric material comprises the same material as the second elastomeric material, and the forming a plurality of dot spacers and the forming an adhesion member are performed substantially simultaneously.

10. The method of claim 8, wherein at least one of the first elastomeric material and the second elastomeric material comprises a rubber-resin composition.

11. The method of claim 10, wherein the rubber-resin composition comprises at least one of polyurethane, polyester and nitrile butadiene rubber.

12. The method of claim 8, wherein the second elastomeric material comprises a rubber-resin composition including an anti-hygroscopic resin.

13. The method of claim 8, wherein each of the first elastomeric material and the second elastomeric material has an elastic coefficient in a range of about 5 to 15 gf/μm.

14. A method for manufacturing a liquid crystal display integrated with a touch panel, the method comprising:
preparing a display panel that comprises:
a first substrate having a first surface, a thin film transistor and a pixel electrode on the first surface,
a second substrate generally spaced a predetermined distance apart from the first substrate and having color filters and a common electrode formed on a surface of the second substrate facing the first surface of the first substrate, and
a liquid crystal layer interposed between the first substrate and the second substrate,
the display panel adapted to display an image;
forming a first transparent electrode on a surface of the second substrate that is opposite to the surface of the second substrate facing the first surface of the first substrate;
forming a plurality of dot spacers on the first transparent electrode, the dot spacers comprising a first elastomeric material;
forming a second transparent electrode on a third substrate;
forming an adhesion member on one of the first transparent electrode and the second transparent electrode, the adhesion member comprising a second elastomeric material having substantially the same thermal expansion coefficient as that of the first elastomeric material; and
after the forming a plurality of dot spacers and the forming an adhesion member, attaching the second substrate and the third substrate to each other such that the adhesion member couples the second substrate to the third substrate, and the first transparent electrode and the second transparent electrode face each other.
